(19) United States
(12) Patent Application Publication
(10) Pub. No.: US 2026/0157227 A1
(43) Pub. Date: Jun. 4, 2026

(54) SEMICONDUCTOR ENCAPSULATING EPOXY RESIN COMPOSITION AND SEMICONDUCTOR DEVICE

(71) Applicant: Panasonic Intellectual Property Management Co., Ltd., Osaka (JP)

(72) Inventors: Yasuaki MAEDA, Mie (JP); Kazuto OGAWA, Mie (JP); Hiroyuki FUJIWARA, Mie (JP)

(21) Appl. No.: 19/122,594

(22) PCT Filed: Jan. 17, 2024
(86) PCT No.: PCT/JP2024/001096

§ 371 Date: Apr. 18, 2025

(30) Foreign Application Priority Data
Jan. 24, 2023 (JP) 2023-008941

(51) Int. Cl. H10W 74/47; H10W 70/40; H10W 74/01; H10W 74/10; H10W 90/00

(52) U.S. Cl. CPC H10W 74/473; H10W 70/417; H10W 70/457; H10W 74/017; H10W 74/129; H10W 90/736; H10W 90/756

(57) ABSTRACT

A semiconductor encapsulating epoxy resin composition contains an epoxy resin (A), a curing agent (B), an inorganic filler (C), and a mold release agent (D). The mold release agent (D) contains a reaction product (d1) of an α-olefin-maleic anhydride copolymer and monofunctional aliphatic glycidyl ether.

### TECHNICAL FIELD

The present disclosure relates to semiconductor encapsulating epoxy resin compositions and semiconductor devices and more specifically relates to a semiconductor encapsulating epoxy resin composition and a semiconductor device including an encapsulation portion formed from the semiconductor encapsulating epoxy resin composition.

### BACKGROUND ART

Patent Literature 1 discloses an epoxy resin composition for encapsulation. This epoxy resin composition includes: an epoxy resin; a curing agent; and a mold release agent, wherein a phenolic curing agent is used as the curing agent, and fatty acid amide and carnauba wax are used as the mold release agent.

### CITATION LIST

### Patent Literature

Patent Literature 1: JP 3417283 B2

### SUMMARY OF INVENTION

It is an object of the present disclosure to provide: a semiconductor encapsulating epoxy resin composition which has good flowability during molding, which provides good mold releasability of a cured product of the semiconductor encapsulating epoxy resin composition from a mold after the molding, and which enables the cured product to have a high degree of adhesion to metal when the semiconductor encapsulating epoxy resin composition is molded on the metal; and a semiconductor device.

A semiconductor encapsulating epoxy resin composition according to an aspect of the present disclosure contains an epoxy resin (A), a curing agent (B), an inorganic filler (C), and a mold release agent (D). The mold release agent (D) contains a reaction product (d1) of an α-olefin-maleic anhydride copolymer and monofunctional aliphatic glycidyl ether.

A semiconductor device according to an aspect of the present disclosure includes a semiconductor element and an encapsulation portion which encapsulates the semiconductor element. The encapsulation portion includes a cured product of the semiconductor encapsulating epoxy resin composition.

### BRIEF DESCRIPTION OF DRAWINGS

FIG. 1 is a schematic sectional view of a semiconductor device according to an embodiment of the present disclosure.

### DESCRIPTION OF EMBODIMENT

### Embodiment

### (1) Overview

It will be described how the present inventors conceived a semiconductor encapsulating epoxy resin composition of the present disclosure (hereinafter also referred to as a composition (X)).

According to knowledge which the inventors uniquely acquired in the course of research and development in an epoxy resin composition for encapsulation, the flowability of the epoxy resin composition for encapsulation during molding and the mold releasability of a cured product, obtained by molding the epoxy resin composition, from a mold may be improved, but in this case, it is difficult to increase the degree of adhesion of the cured product to a metal member, such as a lead frame, included in a semiconductor device.

Thus, the inventors intensively conducted research to be able to obtain a semiconductor encapsulating epoxy resin composition which has good flowability during molding, which provides good mold releasability of a cured product of the semiconductor encapsulating epoxy resin composition from a mold after the molding, and which enables the cured product to have a high degree of adhesion to metal when the semiconductor encapsulating epoxy resin composition is molded on the metal. As a result, the present inventors conceived the concept of the disclosure.

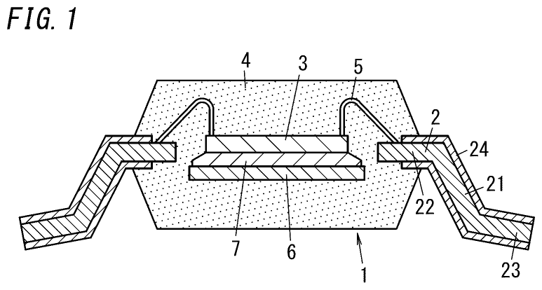

An embodiment will be described with reference to FIG. 1. Note that the embodiment described below is a mere example of various embodiments of the present disclosure. Moreover, various modifications may be made to the embodiment described below as long as the object of the present disclosure is achieved.

FIGURES to be referred to in the following description are schematic representations. Thus, the dimensional ratios of constituent elements in the figures are not always to scale, compared with actual ones.

First of all, the overview of the composition (X) will be described. As described above, the composition (X) contains an epoxy resin (A), a curing agent (B), an inorganic filler (C), and a mold release agent (D). The mold release agent (D) contains a reaction product (d1) of an α-olefin-maleic anhydride copolymer and monofunctional aliphatic glycidyl ether. Thus, the composition (X) has good flowability during molding, provides good mold releasability of a cured product of the composition (X) from a mold after the molding, and enables the cured product to have a high degree of adhesion to metal when the composition (X) is molded on the metal.

This will be described in detail. The α-olefin-maleic anhydride copolymer has a portion derived from the maleic anhydride. When a resin composition contains a copolymer having such a portion derived from the maleic anhydride, a cured product of the resin composition can have an increased degree of adhesion to metal. That is, when the resin composition is molded on a metal member, such as a lead frame, included in the semiconductor device, the cured product can have a high degree of adhesion to metal.

Further, in the case of such an α-olefin-maleic anhydride copolymer, causing the portion derived from the maleic anhydride to react with an appropriate compound can impart, to the α-olefin-maleic anhydride copolymer after the reaction, the effect of increasing the degree of flowability during molding and the degree of mold releasability of the cured product from a mold after the molding. In this case, the effect which the α-olefin-maleic anhydride copolymer has of increasing the degree of adhesion of the cured product to the metal may, however, be impaired depending on the compound used in the reaction. Meanwhile, the inventors found that causing a reaction with a specific compound, that is, monofunctional aliphatic glycidyl ether can impart, to the α-olefin-maleic anhydride copolymer, the effect of increasing the degree of flowability during molding and the degree of mold releasability of the cured product from a mold after the molding without impairing the effect, imparted by the portion derived from the maleic anhydride, of increasing the degree of adhesion of the cured product to the metal. That is, the inventors found that when the composition (X) contains the reaction product (d1) of the α-olefin-maleic anhydride copolymer and monofunctional aliphatic glycidyl ether, the composition (X) has good flowability during molding, provides good mold releasability of a cured product of the composition (X) from a mold after the molding, and enables the cured product to have a high degree of adhesion to metal when the composition (X) is molded on the metal.

Further, the composition (X) as described above may be used to produce a semiconductor device 1. More specifically, the composition (X) may be used to form an encapsulation portion 4 for encapsulating a semiconductor element 3 included in the semiconductor device 1. Note that the application of the composition (X) is not limited to only encapsulating the semiconductor element 3 included in the semiconductor device 1. That is, the composition (X) is usable in various applications.

### (2) Component

Details of the components of the composition (X) will be described.

### (Epoxy Resin)

The composition (X) contains the epoxy resin (A) as a component as described above. Moreover, when the composition (X) is heated, the epoxy resin (A) can react with the curing agent (B). This can cure the composition (X).

The epoxy resin (A) includes at least one component selected from the group consisting of, for example, a glycidyl ether epoxy resin, a glycidyl amine epoxy resin, a glycidyl ester epoxy resin, and an olefin oxidation (alicyclic) epoxy resin. More specifically, the epoxy resin (A) includes at least one component selected from the group consisting of, for example, alkyl-phenol-novolac epoxy resins such as a phenol-novolac epoxy resin and a cresol-novolac epoxy resin; naphthol-novolac epoxy resins; phenol-aralkyl epoxy resins having, for example, a phenylene skeleton or a biphenylene skeleton; biphenyl-aralkyl epoxy resins; naphthol-aralkyl epoxy resins having, for example, a phenylene skeleton or a biphenylene skeleton; polyfunctional epoxy resins such as triphenol-methane epoxy resins and alkyl-modified triphenol-methane epoxy resins; triphenyl-methane epoxy resins; tetrakisphenol ethane epoxy resins; dicyclopentadiene epoxy resins; stilbene epoxy resins; bisphenol epoxy resins such as bisphenol A epoxy resins and bisphenol F epoxy resins; biphenyl epoxy resins; naphthalene epoxy resins; alicyclic epoxy resins; bromine-containing epoxy resins such as bisphenol A bromine-containing epoxy resins; glycidyl-amine epoxy resins produced by reaction between epichlorohydrin and polyamines such as diaminodiphenylmethane and isocyanuric acid; and glycidyl-ester epoxy resins produced by reaction between polybasic acids such as phthalic acid and dimer acid and epichlorohydrin.

Among the components above, the epoxy resin (A) preferably contains at least one selected from the group consisting of a biphenyl epoxy resin, a biphenyl-aralkyl epoxy resin, and a naphthol-novolac epoxy resin. In this case, the cured product can have increased heat resistance, and the flowability during molding can be increased. Note that the epoxy resin (A) may contain only one component or may contain two or more components.

### (Curing Agent)

The composition (X) contains the curing agent (B) as a component as described above. The curing agent (B) preferably contains a phenolic compound. When the curing agent (B) contains the phenolic compound, the curability of the epoxy resin (A) can be further increased because the phenolic compound has good reactivity with the epoxy resin (A).

The phenolic compound contains at least one selected from the group consisting of, for example, monomers, oligomers, and polymers having two or more phenolic hydroxyl groups per molecule.

The phenolic compound includes at least one component selected from the group consisting of, for example: novolac resins such as phenol-novolac resins, cresol-novolac resins, and naphthol-novolac resins; phenol-aralkyl resins having either a phenylene skeleton or a biphenylene skeleton; polyfunctional phenolic resins such as triphenol methane resins; dicyclopentadiene phenolic resins such as dicyclopentadiene phenol-novolac resins and dicyclopentadiene naphthol-novolac resins; terpene-modified phenolic resins; bisphenol resins such as bisphenol A and bisphenol F resins; and triazine-modified novolac resins. Note that the curing agent (B) is not limited to the phenolic compound as long as it causes a thermal curing reaction with the epoxy resin (A). For example, the curing agent (B) contains at least one component of a phenolic compound, an acid anhydride, an imidazole compound, or an amine compound.

The equivalent ratio of the epoxy resin (A) to the curing agent (B) is preferably greater than or equal to 0.6 and less than or equal to 10.0. When the equivalent ratio of the epoxy resin (A) to the curing agent (B) is less than or equal to 10.0, good curability of the composition (X) and good heat resistance and strength of the cured product can be achieved. Moreover, when the equivalent ratio of the epoxy resin (A) to the curing agent (B) is greater than or equal to 0.6, a high degree of moisture resistance of the cured product can be achieved. The equivalent ratio of the epoxy resin (A) to the curing agent (B) is preferably greater than or equal to 0.8. The equivalent ratio of the epoxy resin (A) to the curing agent (B) is more preferably less than or equal to 5.0.

Note that as the curing agent (B), only one component may be used, or two or more components may be used in combination.

### (Inorganic Filler)

The composition (X) contains the inorganic filler (C) as a component as described above. Thus, the cured product can have increased heat resistance. Moreover, the inorganic filler (C) enables the cured product to have a reduced coefficient of linear expansion.

The inorganic filler (C) contains at least one component selected from the group consisting of, for example, molten silica, crystal silica, alumina, zircon, calcium silicate, calcium carbonate, potassium titanate, silicon carbide, silicon nitride, aluminum nitride, boron nitride, beryllia, zirconia, zircon, forsterite, steatite, spinel, mullite, and titania. Note that as the inorganic filler (C), only one component may be used, or two or more components may be used in combination.

The content of the inorganic filler (C) relative to the composition (X) is preferably greater than or equal to 75% by mass and less than or equal to 95% by mass. In this case, the cured product can have further increased heat resistance and a further reduced coefficient of linear expansion.

### (Mold Release Agent)

The composition (X) contains the mold release agent (D) as a component as described above. The mold release agent (D) contains the reaction product (d1) of the α-olefin-maleic anhydride copolymer and monofunctional aliphatic glycidyl ether. This can achieve good flowability during molding and good mold releasability of the cured product from a mold after the molding and enables the cured product to have an increased degree of adhesion to metal when the composition (X) is molded on the metal. Note that the reaction product (d1) may include a plurality of types of compounds.

### [α-Olefin-Maleic Anhydride Copolymer]

As described above, the reaction product (d1) is produced from the α-olefin-maleic anhydride copolymer. Thus, the reaction product (d1) enables the cured product to have an increased degree of adhesion to metal when the composition (X) is molded on the metal.

As concerns the α-olefin-maleic anhydride copolymer, the number of carbon atoms of the α-olefin is preferably greater than or equal to 28 and less than or equal to 60. In this case, the cured product can have an increased degree of adhesion to metal when the cured product is formed on the metal, and the cured product can have increased mold releasability from the mold after the molding. More specifically, when the number of carbon atoms of the α-olefin is greater than or equal to 28, the reaction product (d1) is readily held by the composition (X), and therefore, the reaction product (d1) hardly adheres to the mold, and as a result, the cured product can have increased mold releasability from the mold after the molding. When the number of carbon atoms of the α-olefin is less than or equal to 60, the effect, which the portion derived from the maleic anhydride has, of increasing the degree of adhesion to metal can be further maintained. This enables the cured product to have an increased degree of adhesion to metal when the composition (X) is molded on the metal. Note that in the present disclosure, the mold releasability means continuous moldability, and the continuous moldability means that an operation including forming a cured product of the composition (X) in a mold and taking the cured product out of the mold can be repeated while a force (resistance value) applied when the cured product is taken out of the mold does not exceed a certain fixed numerical value.

The α-olefin employed to produce the α-olefin-maleic anhydride copolymer contains at least one compound selected from the group consisting of, for example, straight-chain α-olefins such as 1-octacosene, 1-triacontene, 1-hentriacontene, 1-dotriacontene, 1-tritriacontene, 1-tetra triacontene, 1-pentatriacontene, 1-hexatriacontene, 1-tetracontene, 1-hentetracontene, 1-dotetracontene, 1-tritetracontene, 1-tetratetracontene, 1-pentacontene, 1-henpentacontene, 1-dopentacontene, 1-tripentacontene, 1-pentapentacontene, and 1-hexacontene, and branched α-olefins such as 3-methyl-1-triacontene, 3,4-dimethyl-triacontene, 3-methyl-1-tetracontene, and 3,4-dimethyl-tetracontene. Moreover, of those compounds, one compound may be employed alone, or two or more compounds may be employed in combination.

As the α-olefin-maleic anhydride copolymer, a commercially available product may be employed. Examples of the commercially available product include Diacarna (registered trademark) 30M (manufactured by Mitsubishi Chemical Corporation) produced from 1-octacosene, 1-triacontene, 1-tetracontene, 1-pentacontene, 1-hexacontene, or the like as a raw material.

The α-olefin-maleic anhydride copolymer has, for example, a structure unit (UA) expressed by the following formula (A) and a structure unit (UB) expressed by the following formula (B).

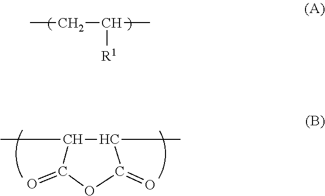

In the formula (A), R¹ represents an alkyl group having greater than or equal to 26 and less than or equal to 56 carbon atoms. The alkyl group may be straight-chain or branched. Moreover, as concerns the α-olefin-maleic anhydride copolymer, the ratio of the structure unit (UA) to the structure unit (UB) is preferably greater than or equal to 0.5 and less than or equal to 10, particularly preferably 1. This facilitates maintenance of: the flowability during molding; the mold releasability of the cured product from the mold after the molding; and the high degree of adhesion of the cured product to metal when the composition (X) is molded on the metal.

The α-olefin-maleic anhydride copolymer preferably includes, for example, at least one of a structure expressed by the following formula (1) or a structure expressed by the following formula (2). This enables the flowability during molding and the mold releasability of the cured product from the mold after the molding to be further increased, and the cured product to have a further increased degree of adhesion to metal when the composition (X) is molded on the metal.

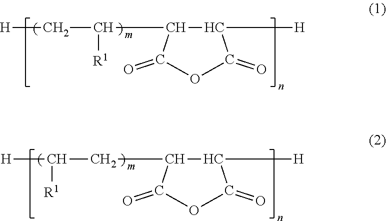

R¹ in the above formulae (1) and (2) may be the same as that in the above formula (A) and represents an alkyl group having greater than or equal to 26 and less than or equal to 56 carbon atoms. n is an integer greater than or equal to 1 and less than or equal to 15. m represents the copolymerization ratio between the α-olefin and the maleic anhydride. m is preferably greater than or equal to 0.5 and less than or equal to 10, and m is particularly preferably 1. That is, the α-olefin-maleic anhydride copolymer particularly preferably has a structure of an α-olefin/maleic anhydride alternating copolymer.

A method for manufacturing the α-olefin-maleic anhydride copolymer may employ any appropriate polymerization method. For the polymerization, for example, an organic solvent in which the α-olefin and the maleic anhydride are soluble may be used. Examples of the organic solvent include aromatic solvents such as toluene, ether-based solvents, and halogen-based solvents. Among these solvents, the organic solvent used in the reaction is preferably toluene. The polymerization temperature differs depending on the type of the organic solvent used, but in terms of productivity, the polymerization temperature is preferably higher than or equal to 50° C. and lower than or equal to 200° C., more preferably higher than or equal to 100° C. and lower than or equal to 150° C. The reaction time is, in terms of productivity, preferably longer than or equal to 1 hour and shorter than or equal to 30 hours, more preferably longer than or equal to 2 hours and shorter than or equal to 15 hours, much more preferably longer than or equal to 4 hours and shorter than or equal to 10 hours.

After the polymerization ends, an unreacting component, the solvent, and the like may be removed, for example, under heated and depressurized conditions. As concerns the heated condition, the temperature is preferably higher than or equal to 100° C. and lower than or equal to 220° C., more preferably higher than or equal to 120° C. and lower than or equal to 180° C. Moreover, as concerns the depressurized condition, the pressure is preferably less than or equal to 13.3×10³ Pa, more preferably less than or equal to 8×10³ Pa. Further, the amount of time required for the removal is preferably longer than or equal to 0.5 hours and shorter than or equal to 10 hours. Moreover, a polymerization initiator may be used for the polymerization. Specific examples of the polymerization initiator include radical polymerization initiators such as azobisisobutyronitrile (AIBN) and benzoyl peroxide (BPO).

### [Monofunctional Aliphatic Glycidyl Ether]

As described above, the reaction product (d1) is produced from monofunctional aliphatic glycidyl ether. Thus, the reaction product (d1) can: maintain the high degree of adhesion of the cured product to metal when the composition (X) is molded on the metal; and increase the degree of flowability during the molding and the degree of mold releasability of the cured product from the mold after the molding.

The monofunctional aliphatic glycidyl ether is, for example, a compound expressed by the following formula (3).

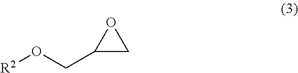

In formula (3), R² is an alkyl group having greater than or equal to 10 and less than or equal to 25 carbon atoms. The alkyl group may be straight-chain or branched.

As concerns the monofunctional aliphatic glycidyl ether, the number of carbon atoms of the monofunctional aliphatic glycidyl ether is preferably greater than or equal to 10 and less than or equal to 25. In this case, the high degree of adhesion of the cured product to metal when the composition (X) is molded on the metal can be further maintained, and the degree of flowability during the molding and the degree of the mold releasability of the cured product from the mold after the molding can be further increased. More specifically, when the number of carbon atoms of the monofunctional aliphatic glycidyl ether is greater than or equal to 10, the reaction product (d1) is further readily held by the composition (X), and therefore, the reaction product (d1) is much less likely to adhere to a mold, thereby further increasing the degree of the mold releasability of the cured product from the mold after the molding. In addition, a reaction of the portion derived from the maleic anhydride of the α-olefin-maleic anhydride copolymer with the monofunctional aliphatic glycidyl ether having 10 or more carbon atoms can further improve the effect of the reaction product (d1) of increasing the degree of flowability of the composition (X). This can further increase the degree of flowability during molding. Further, when the number of carbon atoms of the monofunctional aliphatic glycidyl ether is less than or equal to 25, it is possible to further maintain the effect, which the portion derived from the maleic anhydride of the α-olefin-maleic anhydride copolymer has, of increasing the degree of adhesion to metal. Thus, the high degree of adhesion of the cured product to metal when the composition (X) is molded on the metal can be further maintained. Moreover, the number of carbon atoms of the monofunctional aliphatic glycidyl ether is more preferably greater than or equal to 12, much more preferably greater than or equal to 17. The number of carbon atoms of the monofunctional aliphatic glycidyl ether is more preferably less than or equal to 22, much more preferably less than or equal to 20.

The monofunctional aliphatic glycidyl ether contains at least one selected from the group consisting of, for example, decyl glycidyl ether, undecyl glycidyl ether, dodecyl glycidyl ether, tridecyl glycidyl ether, tetradecyl glycidyl ether, pentadecyl glycidyl ether, hexadecyl glycidyl ether, stearyl glycidyl ether, nonadecyl glycidyl ether, and eicosyl glycidyl ether. Moreover, as the monofunctional aliphatic glycidyl ether, one of the above compounds may be used alone, or two or more of the above compounds may be used in combination.

### [Reaction Product]

The reaction product (d1) can be produced by causing the α-olefin-maleic anhydride copolymer to react with the monofunctional aliphatic glycidyl ether. More specifically, the reaction product (d1) can be produced by the reaction of the portion derived from the maleic anhydride included in the α-olefin-maleic anhydride copolymer with the monofunctional aliphatic glycidyl ether. In still other words, the reaction product (d1) can have a structure unit (UC) expressed by the following formula (C).

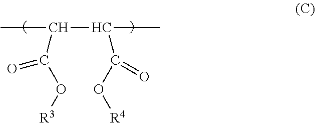

R³ and R⁴ are each independently a hydrogen atom or a group generated by the reaction of the monofunctional aliphatic glycidyl ether expressed by the above formula (3).

Note that the reaction product (d1) has the structure unit (UC) expressed by formula (C) and may have a plurality of structure units having structures different from each other. In this case, the structure units (UC) different from each other can differ in at least one of R³ or R⁴.

Moreover, to produce the reaction product (d1) from the α-olefin-maleic anhydride copolymer, not all of portions derived from the maleic anhydride in the copolymer have to react with the monofunctional aliphatic glycidyl ether. That is, some of the portions derived from the maleic anhydride may remain in the reaction product (d1), and the reaction product (d1) may have the structure unit (UB) in addition to the structure unit (UC). More specifically, the reaction product (d1) may have the structure unit (UA) and the structure unit (UB) in addition to the structure unit (UC).

To produce the reaction product (d1), the ratio by weight between the α-olefin-maleic anhydride copolymer and the monofunctional aliphatic glycidyl ether used in the reaction may be adjusted in accordance with the types of the α-olefin-maleic anhydride copolymer and the monofunctional aliphatic glycidyl ether. That is, the ratio by weight between the α-olefin-maleic anhydride copolymer and the monofunctional aliphatic glycidyl ether used in the reaction may be adjusted such that the composition (X) has good flowability during molding, provides good mold releasability of a cured product of the composition (X) from a mold after the molding, and enables the cured product to have a high degree of adhesion to metal when the composition (X) is molded on the metal.

Moreover, the ratio by weight between the α-olefin-maleic anhydride copolymer and the monofunctional aliphatic glycidyl ether used in the reaction may be adjusted such that the ratio of the structure unit (UA), structure unit (UB), and structure unit (UC) included in the reaction product (d1) can be adjusted to a preferable ratio. Further, as concerns the structure unit (UC), the ratio by weight between the α-olefin-maleic anhydride copolymer and the monofunctional aliphatic glycidyl ether may be adjusted such that a structure obtained by reacting only one monofunctional aliphatic glycidyl ether with one portion derived from the maleic anhydride and a structure obtained by reacting two monofunctional aliphatic glycidyl ethers with one portion derived from the maleic anhydride are included in an appropriate ratio.

As concerns the production of the reaction product (d1), the ratio by weight between the α-olefin-maleic anhydride copolymer and the monofunctional aliphatic glycidyl ether used in the reaction is preferably greater than or equal to 6:1 and less than or equal to 1:6. This can achieve better flowability during molding and better mold releasability of the cured product from the mold after the molding and enables the cured product to have an increased degree of adhesion to metal when the composition (X) is molded on the metal. The ratio by weight between the α-olefin-maleic anhydride copolymer and the monofunctional aliphatic glycidyl ether used in the reaction is more preferably greater than or equal to 4:1 and less than or equal to 1:4, particularly preferably 2:1.

In the reaction, for example, an organic solvent in which the α-olefin-maleic anhydride copolymer and the monofunctional aliphatic glycidyl ether are soluble may be used. Examples of the organic solvent include aromatic solvents such as toluene, ether-based solvents, and halogen-based solvents. Among these solvents, the organic solvent used in the reaction is preferably toluene. Note that the reaction may be caused without using the solvent.

The reaction temperature can be adjusted accordingly depending on the type of the organic solvent used. The reaction temperature is preferably higher than or equal to 50° C. and lower than or equal to 200° C. In this case, the productivity can be improved. Moreover, the reaction temperature is more preferably higher than or equal to 100° C. and lower than or equal to 150° C. The reaction time is preferably longer than or equal to 10 minutes and shorter than or equal to 30 hours. In this case, the productivity can be improved. The reaction time is more preferably longer than or equal to 30 minutes.

Moreover, after the reaction ends, an unreacting component, the solvent, and the like may be removed, for example, under heated and depressurized conditions. As concerns the heated condition, the temperature is preferably higher than or equal to 100° C. and lower than or equal to 220° C., more preferably higher than or equal to 120° C. and lower than or equal to 180° C. Moreover, as concerns the depressurized condition, the pressure is preferably less than or equal to 13.3×10³ Pa, more preferably less than or equal to 8×10³ Pa. Moreover, the amount of time required for the removal is preferably longer than or equal to 0.5 hours and shorter than or equal to 10 hours.

Further, the reaction may employ a reaction catalyst, for example, an amine-based catalyst such as triphenyl phosphine, triethyl amine, and N, N-dimethyl amino pyridine, and an acid catalyst such as sulfuric acid and p-toluenesulfonic acid as necessary.

As described above, the α-olefin-maleic anhydride copolymer preferably has, for example, at least one of the structures expressed by the above formulae (1) and (2). That is, the reaction product (d1) preferably has, for example, at least one of the structures expressed by the following formulae (4) and (5).

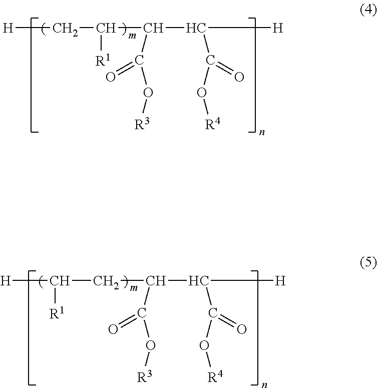

R¹ in the above formulae (4) and (5) may be the same as R¹ in the above formulae (1) and (2) and is an alkyl group having greater than or equal to 26 and less than or equal to 56 carbon atoms. m is preferably greater than or equal to 0.5 and less than or equal to 10, particularly preferably 1.

R³ and R⁴ are each independently a hydrogen atom or a group generated by the reaction of the monofunctional aliphatic glycidyl ether expressed by the above formula (3).

Further, when the reaction product (d1) has at least one of the structures expressed by the above formulae (4) and (5), each of R³ and R⁴ in the above formulae (4) and (5) is preferably a group expressed by the following formula (6). This can achieve particularly good flowability during molding and the mold releasability of the cured product from the mold after the molding. Moreover, when the reaction product (d1) has at least one of the structures expressed by the above formulae (4) and (5), each of R³ and R⁴ in the above formulae (4) and (5) is preferably a group expressed by the following formula (7). This enables the cured product to have a particularly increased degree of adhesion to metal when the composition (X) is molded on the metal. That is, in the present embodiment, when the reaction product (d1) has at least one of the structures expressed by the above formulae (4) and (5), each of R³ and R⁴ in the above formulae (4) and (5) is preferably at least one of a group expressed by the following formula (6) or a group expressed by the following formula (7).

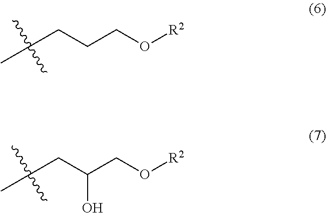

R² in the above formulae (6) and (7) may be the same as R² in the above formula (3) and is an alkyl group having greater than or equal to 10 and less than or equal to 25 carbon atoms. Moreover, R² is preferably an alkyl group having greater than or equal to 7 and less than or equal to 22 carbon atoms. Further, the alkyl group may be straight-chain or branched.

Moreover, the content of the reaction product (d1) is preferably greater than or equal to 10% by mass relative to the content of the mold release agent (D). This can particularly increase the degrees of flowability during molding, mold releasability of the cured product from the mold after the molding, and adhesion of the cured product to metal when the composition (X) is molded on the metal. The content of the reaction product (d1) is more preferably greater than or equal to 20% by mass, much more preferably greater than or equal to 30% by mass, relative to the content of the mold release agent (D). The content of the reaction product (d1) is preferably less than or equal to 95% by mass, more preferably less than or equal to 90% by mass, relative to the content of the mold release agent (D).

Note that the mold release agent (D) may include, in addition to the reaction product (d1), a component (hereinafter referred to as a mold release agent (d2)) other than the reaction product (d1). The mold release agent (d2) is at least one selected from the group consisting of, for example, natural Carnauba-based wax such as Carnauba wax, and a polyethylene-based wax containing higher fatty acid, such as stearic acid and montanic acid, and a carboxyl group. Of these mold release agents (d2), one agent may be used alone, or two or more agents may be used in combination.

### (Additive)

The composition (X) may contain, in addition to the epoxy resin (A), the curing agent (B), the inorganic filler (C), and the mold release agent (D), a component (hereinafter referred to as an additive (E) other than the epoxy resin (A), the curing agent (B), the inorganic filler (C), and the mold release agent (D). The additive (E) may contain at least one selected from the group consisting of, for example, a curing accelerator, a coupling agent, pigment, a fire retardant, a colorant, and an adhesion accelerator.

The composition (X) may further contain the curing accelerator as described above. The curing accelerator contains at least one component selected from the group consisting of, for example, cycloamidines compounds such as 1,8-diaza-bicyclo[5.4.0]undecene-7, 1,5-diaza-bicyclo[4.3.0]nonene, and 5,6-dibutyl amino-1,8-diaza-bicyclo[5.4.0]undecene-7; tertiary amine compounds such as benzil dimethyl amine, triethanol amine, dimethyl amino ethanol, tris(dimethylaminomethyl)phenol, and derivatives thereof, imidazole compounds such as 2-methylimidazole, 2-phenyl imidazole, 2-phenyl-4-methylimidazole, and derivatives thereof; organic phosphorus compounds such as organic phosphines such as tributyl phosphine, methyl diphenyl phosphine, triphenyl phosphine, tris(4-methylphenyl)phosphine, diphenyl phosphine, and phenyl phosphine, and compounds having intermolecular polarization and obtained by adding, to these organic phosphines, compounds having a π bond such as bisphenol A, bisphenol F, bisphenol S, and a phenol resin, a quinone compound such as 1,4-benzoquinone, 2,5-toluquinone, 1,4-naphthoquinone, 2,3-dimethyl benzoquinone, 2,6-dimethyl benzoquinone, 2,3-dimethoxy-5-methyl-1,4-benzoquinone, 2,3-dimethoxy-1,4-benzoquinone, and phenyl-1,4-benzoquinone; and tetraphenyl boron salts such as tetraphenylphosphonium tetraphenylborate, triphenylphosphine tetraphenylborate, and derivatives thereof. Of these components, one component may be used alone, or two or more components may be used in combination.

The composition (X) may further contain the coupling agent as described above. The coupling agent contains at least one selected from the group consisting of, for example, various kinds of silane-based compounds such as epoxysilane, mercaptosilane, aminosilane, alkylsilane, ureidosilane, vinylsilane, titanium-based compounds, aluminum chelates, and aluminum/zirconium-based compounds. Specifically, the coupling agent contains at least one component selected from the group consisting of, for example, silane-based compounds such as vinyl triethoxysilane, vinyl tris(β-methoxy ethoxy)silane, γ-methacryloxy propyltrimethoxysilane, 3-(3,4-epoxy cyclohexyl)ethyltrimethoxysilane, γ-glycidoxy propyltrimethoxysilane, γ-glycidoxy propylmethyldimethoxysilane, γ-glycidoxy propyltriethoxysilane, vinyltriacetoxysilane, γ-mercapto propyltrimethoxysilane, γ-mercapto propylmethyldimethoxysilane, γ-mercapto propyltriethoxysilane, γ-amino propyltrimethoxysilane, γ-amino propylmethyldimethoxysilane, γ-amino propyltriethoxysilane, γ-anilino propyltrimethoxysilane, γ-anilino propylmethyldimethoxysilane, N-β-(aminoethyl)-γ-amino propyltrimethoxysilane, γ-(β-aminoethyl)amino propyl dimethoxy methyl silane, N-(trimethoxy silyl propyl)ethylene diamine, N-(dimethoxy methyl silyl isopropyl)ethylene diamine, N-β-(N-vinyl benzil aminoethyl)-γ-amino propyltrimethoxysilane, γ-chloro propyltrimethoxysilane, hexamethyldisilane, and vinyl trimethoxy silane; and titanium-based compounds such as isopropyl triisostearoyl titanate, isopropyl tris(dioctyl pyrophosphate)titanate, isopropyl tri(N-aminoethyl-aminoethyl)titanate, tetra octyl bis(ditridecyl phosphite)titanate, tetra (2,2-diallyl oxy methyl-1-butyl)bis(ditridecyl)phosphite titanate, bis(dioctyl pyrophosphate)oxy acetate titanate, bis(dioctyl pyrophosphate)ethylene titanate, isopropyl trioctanoyl titanate, isopropyl dimethacryl isostearoyl titanate, isopropyl tridodecyl benzene sulfonyl titanate, isopropyl isostearoyl diacryl titanate, isopropyl tri(dioctyl phosphate)titanate, isopropyl tricumyl phenyl titanate, and tetra isopropyl bis(dioctyl phosphite)titanate. Of these components, one component may be used alone, or two or more components may be used in combination.

### (3) Manufacturing Method

A method for manufacturing the composition (X) will be described.

The composition (X) may be prepared by any method as long as the method can homogeneously disperse and mix various kinds of raw materials. Examples of a common method include a method of: mixing prescribed blending amounts of raw materials by using, for example, a mixer; then, melting and kneading the raw materials by using, for example, a mixing roll, a kneader, or an extruder to obtain a mixture; and cooling and pulverizing the mixture.

Moreover, the composition (X) pulverized in the method described above may be used in tablet form. Alternatively, the composition (X) may be dissolved in various kinds of organic solvents to be used as a liquid resin composition. Thinly applying the liquid resin composition onto a plate or a film and then removing the organic solvent enables the composition (X) to be used as a sheet-shaped or film-shaped composition (X).

### (4) Physical Property

The physical property of the composition (X) will be described.

### [Gel Time]

As concerns the composition (X), the amount of time (gel time) required for a torque value measured with respect to 1.67 mL of the composition (X) under conditions of 170° C. to be 0.1 kgf·cm is, for example, longer than or equal to 15 seconds and shorter than or equal to 80 seconds. When the gel time is longer than or equal to 15 seconds, good flowability in forming the encapsulation portion from the composition (X) can be maintained. When the gel time is shorter than or equal to 80 seconds, a good curing speed of the composition (X) can be maintained. The gel time is preferably longer than or equal to 30 seconds and is preferably shorter than or equal to 60 seconds. The torque value is, specifically, measured by using a curelastometer test device, wherein temperatures at upper and lower surfaces of a mold of the curelastometer test device are set to 170° C., and a 1.67 mL sample of the composition (X) is injected into the mold. In the present disclosure, “the amount of time required for a torque value measured with respect to the 1.67 mL sample under conditions of 170° C. to be 0.1 kgf·cm” is also referred to as the gel time. Note that to measure the torque value and the gel time, 1.67 mL of the composition (X) are used as a measurement sample, but this should not be construed as limiting the amount of the composition (X) when the cured product is produced in the present disclosure.

### [Continuous Moldability]

The cured product of the composition (X) can exhibit good continuous moldability. Specifically, a force (resistance value) when a cured product obtained by molding the composition (X) under conditions of a molding temperature of 175° C. and a cure time of 180 seconds is lifted out of the mold is preferably less than 40N. More specifically, a case of the resistance value being greater than or equal to 40N is preferably not confirmed until a series of operation of producing a cured product in a mold and subsequently lifting the cured product out of the mold has been repeated 20 or more times. The case of the resistance value being greater than or equal to 40N is more preferably not confirmed until the operation has been repeated 40 or more times. The case of the resistance value being greater than or equal to 40N is much more preferably not confirmed until the operation has been repeated 60 or more times.

Note that the resistance value is measurable by using a digital force gauge. Examples of a method for molding the composition (X) include a method using, for example, an appropriate molding machine.

### [Adhesion to Metal]

The cured product of the composition (X) can have a high degree of adhesion to metal when the composition (X) is molded on the metal. For example, the adhesion of the cured product of the composition (X) to the metal is greater than or equal to 12 MPa. The adhesion to the metal can be confirmed by: causing adhesion test pieces each in 2.5 mmcφ×3 mm molded under conditions of a molding temperature of 175° C., an injection pressure of 9.8 MPa, and a cure time of 150 seconds by using a transfer molding machine to adhere to adherends; measuring adhesion strengths (shear strengths) between the adhesion test pieces and the adherends at a room temperature by using an automatic die shear measurement device; and calculating an average value of the adhesion strengths. Note that the number of adhesion test pieces is, for example, six.

More specifically, a preferable property of the composition (X) described above is achievable by accordingly adjusting the above-described components of the composition (X). Note that the physical property of the composition (X) is not limited only to the above-described physical property.

### (5) Application Example

Application examples of the composition (X) will be described.

As described above, the composition (X) of the present embodiment is suitably usable to form the encapsulation portion 4 of the semiconductor device 1. The semiconductor device 1 includes the semiconductor element 3 and the encapsulation portion 4 encapsulating the semiconductor element 3. The encapsulation portion 4 is formed from the composition (X). That is, the encapsulation portion 4 includes a cured product of the composition (X) (see FIG. 1). Examples of the semiconductor device 1 and a method for manufacturing the semiconductor device 1 will be described below.

Examples of the semiconductor device 1 include a single in-line package (SIP), a zig-zag in-line package (ZIP), a dual in-line package (DIP), a small outline package (SOP), a small outline J-leaded package (SOJ), a small outline I-leaded package (SOI), a small outline F-leaded package (SOF), a quad flat package (QFP), a quad flat J-leaded package (QFJ), a quad flat I-leaded package (QFI), a quad flat F-leaded package (QFF), apin grid array (PGA), aplastic ball grid array (PBGA), a fine pitch ball grid array (FBGA), a wafer level package (WLP), a panel level package (PLP), a fan-out wafer level package (FO-WLP), a fan-out panel level package (FO-PLP), a flip chip-ball grid array (FC-BGA), an antenna in package (AiP), and a system in package (SiP).

FIG. 1 shows a sectional view of the semiconductor device 1 of the present embodiment. The semiconductor device 1 includes a lead frame 2 made of metal, the semiconductor element 3 mounted on the lead frame 2, wires 5 which electrically connect the semiconductor element 3 to the lead frame 2, and the encapsulation portion 4, which encapsulates the semiconductor element 3.

In the present embodiment, the lead frame 2 includes a paddle 6 (also referred to a die pad) and lead fingers 21, and each lead finger 21 has an inner lead 22 and an outer lead 23. The lead fingers 21 are made of, for example, copper or an iron alloy such as Alloy 42. The lead frame 2 further includes a plating layer 24 which covers the lead fingers 21. This reduces the corrosion of the lead fingers 21. The plating layer 24 includes at least one metal selected from the group consisting of, for example, silver, nickel, and palladium. The plating layer 24 may include only one of silver, nickel, and palladium or may include an alloy including at least one of silver, nickel, or palladium. The plating layer 24 may have a multilayer structure and may specifically have a multilayer structure including at least one or more layers selected from the group consisting of, for example, a silver layer, a nickel layer, and a palladium layer stacked one on top of another. The thickness of the plating layer 24 is, for example, within the range from 1 μm to 20 μm, both inclusive, but is not particularly limited to this example.

Then, the semiconductor element 3 is fixed with an appropriate die bonding material 7 onto the die pad 6 of the lead frame 2. In this manner, the semiconductor element 3 can be mounted onto the lead frame 2. The semiconductor element 3 is, for example, an integrated circuit, a large scale integrated circuit, a transistor, a thyristor, a diode, or a solid-state image sensor. The semiconductor element 3 may be a novel power device such as a SiC-based device or a GaN-based device.

Subsequently, the semiconductor element 3 is connected to the inner leads 22 of the lead frame 2 via the wires 5. The wires 5 may be made of gold and may include at least one of silver or copper. For example, the wires 5 may be made of silver or copper. When the wires 5 include at least one of silver or copper, the wires 5 may be coated with a thin film of metal such as palladium.

Subsequently, the composition (X) is molded, thereby forming the encapsulation portion 4 encapsulating the semiconductor element 3. Moreover, the encapsulation portion 4 may also encapsulate the wires 5 at this time. The encapsulation portion 4 may further encapsulate the die pad 6 and the inner leads 22, and in this case, the encapsulation portion 4 is in contact with the lead frame 2. Moreover, when the lead frame 2 includes the plating layer 24, the encapsulation portion 4 may be in contact with the plating layer 24.

For example, the encapsulation portion 4 may be formed by molding the composition (X) by a pressure molding method. Examples of the pressure molding method include an injection molding method, a transfer molding method, and a compression molding method. Moreover, a condition under which the composition (X) is molded by the pressure molding method is accordingly set in accordance with the composition of the composition (X). For example, when the composition (X) is molded by the pressure molding method, the molding pressure is, for example, greater than or equal to 3.0 MPa, and the molding temperature is higher than or equal to 120° C.

In the case of the transfer molding method, in particular, the composition (X) is injected into a mold at an injection pressure of, for example, greater than or equal to 3.0 MPa, preferably greater than or equal to 4.0 MPa and less than or equal to 710 MPa. Moreover, the heating temperature (mold temperature) is preferably higher than or equal to 120° C., more preferably higher than or equal to 160° C. and lower than or equal to 190° C. Moreover, the heating duration is, for example, longer than or equal to 30 seconds and shorter than or equal to 300 seconds, more preferably longer than or equal to 60 seconds and shorter than or equal to 180 seconds. Moreover, in the case of the transfer molding method, after the encapsulation portion 4 has been formed in the mold, post curing may be conducted by heating the encapsulation portion 4 with the mold kept closed, and then, the semiconductor device 1 may be unloaded with the mold opened. The heating condition for the post curing may include, for example, a heating duration higher than or equal to 160° C. and lower than or equal to 190° C. and a heating duration longer than or equal to 2 hours and shorter than or equal to 8 hours.

The semiconductor device 1 is unloaded from the mold after the molding. In the present embodiment, the encapsulation portion 4 of the semiconductor device 1 is formed from the composition (X). Therefore, the encapsulation portion 4 has good mold releasability from the mold, and the semiconductor device 1 is thus readily released from the mold. More specifically, a force (resistance) when the semiconductor device 1 is lifted out of the mold is reduced, and the mold release agent (D) of the composition (X) is less likely to adhere to the mold, and therefore, the mold is less likely to be stained.

Thus, the semiconductor device 1 having the encapsulation portion 4 formed from the composition (X) is obtained. The encapsulation portion 4 included in the semiconductor device 1 is formed from the composition (X). The composition (X) enables the cured product to have a high degree of adhesion to metal when the composition (X) is molded on the metal. That is, the adhesion between the encapsulation portion 4 and the lead frame 2 is good. Note that the method of manufacturing the semiconductor device 1 is not limited to the method described above as long as it can encapsulate electronic components, such as the semiconductor element 3, of the semiconductor device 1 by filling with the composition (X) described above.

### SUMMARY

As can be seen from the foregoing description of the embodiment, the present disclosure has the following aspects. In the following description, reference signs are inserted in parentheses just for the sake of clarifying correspondence in constituent elements between the following aspects of the present disclosure and the embodiment described above.

A composition (X) of a first aspect of the present disclosure contains an epoxy resin (A), a curing agent (B), an inorganic filler (C), and a mold release agent (D). The mold release agent (D) contains a reaction product (d1) of an α-olefin-maleic anhydride copolymer and monofunctional aliphatic glycidyl ether.

The first aspect enables a composition (X) to be provided which has good flowability during molding, which provides good mold releasability of a cured product of the composition (X) from a mold after the molding, and which enables the cured product to have a high degree of adhesion to metal when the composition (X) is molded on the metal.

A composition (X) of a second aspect of the present disclosure referring to the first aspect, the reaction product (d1) has a structure unit expressed by formula (C).

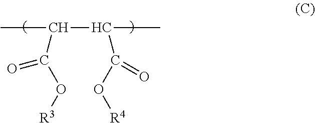

where R³ and R⁴ are each independently a hydrogen atom, a group expressed by formula (6), or a group expressed by formula (7), and at least one of R³ or R⁴ is the group expressed by formula (6) or the group expressed by formula (7).

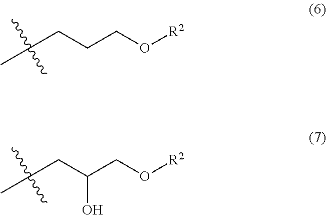

R² in formulae (6) and (7) is an alkyl group having greater than or equal to 10 and less than or equal to 25 carbon atoms.

In a composition (X) of a third aspect of the present disclosure referring to the first or second aspect, a content of the reaction product (d1) is greater than or equal to 10% by mass relative to a content of the mold release agent (D).

The third aspect enables the degrees of flowability during molding, mold releasability of the cured product from the mold after the molding, and adhesion of the cured product to the metal to be particularly increased.

In a composition (X) of a fourth aspect of the present disclosure referring to any one of the first to third aspects, the epoxy resin (A) contains at least one selected from the group consisting of a biphenyl epoxy resin, a biphenyl-aralkyl epoxy resin, and a naphthol-novolac epoxy resin.

The fourth aspect enables the cured product to have increased heat resistance and the flowability during molding to be increased.

In a composition (X) of a fifth aspect of the present disclosure referring to any one of the first to fourth aspect, a content of the inorganic filler (C) is greater than or equal to 75% by mass and less than or equal to 95% by mass relative to the composition (X).

The fifth aspect enables the cured product to have further increased heat resistance and a further reduced coefficient of linear expansion.

In a composition (X) of a sixth aspect of the present disclosure referring to any one of the first to fifth aspect, the monofunctional aliphatic glycidyl ether has greater than or equal to 10 and less than or equal to 25 carbon atoms.

The sixth aspect enables the high degree of adhesion of the cured product to the metal to be maintained, the degrees of the flowability during the molding and the mold releasability of the cured product from the mold after the molding to be further increased.

A semiconductor device (1) of a seventh aspect of the present disclosure includes a semiconductor element (3) and an encapsulation portion (4) which encapsulates the semiconductor element (3). The encapsulation portion (4) includes a cured product of the composition (X) of any one of the first to sixth aspects.

### EXAMPLES

The present disclosure will be described in detail below with reference to examples, but the present disclosure is not limited to these examples.

### 1. Method for Producing Resin Composition

A method for producing resin compositions of Examples 1 to 3 and Comparative Examples 1 to 4 will be described.

### [Components]

Components employed to produce the resin compositions of Examples 1 to 3 and Comparative Examples 1 to 4 will be described below.

### (Epoxy Resin)

Epoxy resin 1: a biphenyl epoxy resin (manufactured by Mitsubishi Chemical Corporation, product name Epikote YX-4000H (epoxy equivalent 187 to 197 g/eq., melting point 105° C.)).

Epoxy resin 2: a bisphenol A (biphenyl-aralkyl) epoxy resin (manufactured by Mitsubishi Chemical Corporation, product name Epikote YL-6810 (epoxy equivalent 165 to 180 g/eq., melting point 45° C.)).

Epoxy resin 3: a naphthylene-ether (naphthol-novolac) epoxy resin (manufactured by DIC Corporation, product name EPICLON HP-6000L (epoxy equivalent 218 g/eq., softening point 59° C.)).

### (Curing Agent)

Curing Agent 1: a phenol-aralkyl phenol resin having a biphenylene skeleton (manufactured by MEIWA PLASTIC INDUSTRIES, LTD., product name MEH7851-SS).
Curing agent 2: a novolac phenol resin (manufactured by MEIWA PLASTIC INDUSTRIES, LTD., product name DL92).

### (Inorganic Filler)

Inorganic filler 1: spherical alumina (manufactured by NIPPON STEEL Chemical & Material Co., LTD., product name AX3-20R).
Inorganic Filler 2: molten spherical silica (manufactured by Denka Company Limited, product name FB-5SDC).
Inorganic filler 3: spherical silica (manufactured by Admatechs Company Limited, product name SO-25R).

### (Mold Release Agent)

Mold release agent 1: natural ester wax (manufactured by Dainichi Chemical Industry Co., LTD., product name carnauba wax F1-100).
Mold release agent 2: montanic acid bisamide (manufactured by Dainichi Chemical Industry Co., LTD., product name J-900).
Mold release agent 3: an α-olefin-maleic anhydride copolymer (manufactured by Mitsubishi Chemical Corporation, product name Diacarna (registered trademark) 30M).
Mold release agent 4: a reaction product obtained in Synthesis Example 1 below (reaction product of Diacarna (registered trademark) 30M and Epogosey LA(D)).
Mold release agent 5: a reaction product obtained in Synthesis Example 2 below (reaction product of Diacarna (registered trademark) 30M and stearyl glycidyl ether).
Mold release agent 6: a reaction product obtained in Synthesis Example 3 below (reaction product of Diacarna (registered trademark) 30M and RIKARESIN BEO-60E).

### (Curing Accelerator)

Curing accelerator 1: a phosphorus curing accelerator (manufactured by San-Apro LTD., U-CAT RP701).

### (Coupling Agent)

Silane coupling agent 1: a silane coupling agent having an aniline structure as an organic functional group (manufactured by Shin-Etsu Silicone Co., LTD., product name KBM573).
Silane coupling agent 2: a silane coupling agent having a mercapto group as an organic functional group (manufactured by Shin-Etsu Silicone Co., LTD., product name KBM803).

### (Pigment)

Pigment 1: Carbon black (manufactured by Mitsubishi Chemical Corporation, product name MA600).

### (As to Mold Release Agents 4 to 6)

In accordance with methods (Synthesis Examples 1 to 3) described below, α-olefin-maleic anhydride copolymers were reacted with respective glycidyl ethers, thereby producing the mold release agents 4 to 6.

### Synthesis Example 1: Synthesis of Mold Release Agent 4 by Reaction of α-Olefin-Maleic Anhydride Copolymer with Monofunctional Aliphatic Glycidyl Ether Having 15 Carbon Atoms

Twenty grams of a copolymer (manufactured by Mitsubishi Chemical Corporation, product name Diacarna(registered trademark) 30M) of a maleic anhydride and a mixture of, for example, 1-octacosene, 1-triacontene, 1-tetracontene, 1-pentacontene, and 1-hexacontene, 10 g of lauryl glycidyl ether (manufactured by Yokkaichi Chemical Company Limited, product name Epogosey LA(D)), and 0.30 g of triphenyl phosphine (manufactured by HOKKO CHEMICAL INDUSTRY CO., LTD., product name TX-TPP) were mixed, dissolved, and caused to react at 120° C. for 0.5 hours, thereby obtaining the mold release agent 4.

### Synthesis Example 2: Synthesis of Mold Release Agent 5 by Reaction of α-Olefin-Maleic Anhydride Copolymer with Monofunctional Aliphatic Glycidyl Ether Having 19 Carbon Atoms

The mold release agent 5 was obtained by a method similar to the method described in Synthesis Example 1 except that 20 g of stearyl glycidyl ether (manufactured by Yokkaichi Chemical Company Limited, product name: Stearyl glycidyl ether) were used as an alternative to the lauryl glycidyl ether.

### Synthesis Example 3: Synthesis of Mold Release Agent 6 by Reaction of α-Olefin-Maleic Anhydride Copolymer with Bifunctional Aromatic Glycidyl Ether

The mold release agent 6 was obtained by a method similar to the method described in Synthesis Example 1 except that 20 g of bisphenol A bis(triethylene glycol glycidyl ether)ether (bifunctional aromatic glycidyl ether having 33 carbon atoms) (manufactured by New Japan Chemical Co, LTD., product name RIKARESIN BEO-60E) were used as an alternative to the lauryl glycidyl ether.

### [Tableting]

The resin compositions of Examples 1 to 3 and Comparative Example 1 to 4 were tableted by the following method. First of all, the components, each in the parts by mass shown in Table 1, were homogeneously mixed and dispersed by using a mixer and were molten and blended by using a kneader at a blending temperature from 90 to 140° C. Subsequently, the resin composition of each of the examples and the comparative examples thus obtained by being molten and blended were cooled and then pulverized, and were compressed, thereby producing tablets of the resin composition.

### 2. Evaluation

The resin compositions of the examples and the comparative examples produced in accordance with the methods described in “1. Method for Producing Resin Composition” were evaluated by tests described below.

### (1) Spiral Flow

According to ASTM D3123, the resin composition of each of the examples and the comparative examples was molded by using a spiral flow mold under conditions of a molding temperature of 170° C., an injection pressure of 70 kgf/cm², and a molding time of 180 seconds, and the distance of flow (flow distance) for 180 seconds from the start of molding was measured. The results are shown in Table 1.

### (2) Gel Time

The torque value of a 1.67 mL sample of the resin composition of each of the examples and the comparative examples was measured by using a curelastometer test device (manufactured by JSR Corporation, product name Curelastometer III PS) with the temperatures of upper and lower surfaces of the mold being 170° C., and the amount of time required for the torque value to be 0.1 kgf·cm was read as the gel time. The results are shown in Table 1.

(3) Evaluation of Adhesion Strength Six adhesion test pieces (2.5 mmφ×3 mm) of the resin composition were molded by using a transfer molding machine (manufactured by Marushichi Co. LTD., product name MF-030 type 30t press) with a 25 mm square highly conducting heat-resistant alloy KFC having a thickness of 0.5 mm (Kobe Steel, LTD., H Grade) used as an adherend under conditions of a molding temperature of 175° C., an injection pressure of 9.8 MPa, and a cure time of 150 seconds. Then, the shear strength between each test piece and the adherend was measured by using an automatic die shear measurement device (manufactured by Nordson Advanced Technology LLC, product name DAGE4000 Optima) at a room temperature. An average value of measured values of the shear strength of the six adhesion test pieces was calculated, and the results are shown and Table 1.

### (4) Continuous Moldability

After a substrate having a dimension of 70 mm×70 mm in plan view was set in a mold of a molding machine (manufactured by Dai-ichi Seiko Co., LTD., product name S Pot), the resin composition of each of the examples and the comparative examples prepared in the mold was molded under conditions of a molding temperature of 175° C. and a cure time of 180 seconds, thereby producing a molded body in the mold. Immediately afterwards, the substrate is lifted out of the mold, and thereby, the molded body is released from the mold.

One operation includes producing the molded body in the mold and releasing the molded body from the mold, and while a force (resistance value) required for lifting the molded body out of the mold is measured by using a digital force gauge (manufactured by IMADA Co., Ltd., product name ZTS-DPU-100N), the continuous moldability was evaluated based on the following criteria. The results are shown in Table 1.
A: The operation was able to be repeated 60 times without the measured value showing a resistance value greater than or equal to 40N.
B: The resistance value reached or exceeded 40N in a period during which the 41st to 60th operations were performed.
C: The resistance value reached or exceeded 40N in a period during which the 21st to 40th operations were performed.
D: The resistance value reached or exceeded 40N in a period during which the 0th to 20th operations were performed.

As concerns the evaluation of the continuous moldability, the operation is to be repeated 60 times, but if a measured value greater than or equal to 40N was confirmed by the time of the 60th operation, the measurement was ended at that time.

TABLE 1

| | | | | | | Comparative | Comparative | Comparative | Comparative |
|---|---|---|---|---|---|---|---|---|---|
| | | | Example 1 | Example 2 | Example 3 | Example 1 | Example 2 | Example 3 | Example 4 |
| Composition | Epoxy | Epoxy Resin 1 | 3.7 | 3.7 | 3.7 | 3.7 | 3.7 | 3.7 | 3.7 |
| (parts by | Resin | Epoxy Resin 2 | 1.2 | 1.2 | 1. [symbol] | 1.2 | 1.2 | 1.2 | 1.2 |
| mass) | | Epoxy Resin 3 | 1.2 | 1.2 | 1. [symbol] | 1.2 | 1.2 | 1.2 | 1.2 |
| | Curing | Curing Agent 1 | 2.4 | 2.4 | 2.4 | 2.5 | 2.5 | 2.5 | 2.4 |
| | Agent | Curing Agent 2 | 1.8 | 1.8 | 1.8 | 1.8 | 1.8 | 1.8 | 1.8 |
| | Inorganic | Inorganic Filler 1 | 48.7 | 48.7 | 48.7 | 48.7 | 48.7 | 48.7 | 48.7 |
| | Filler | Inorganic Filler 2 | 26. [symbol] | 26.6 | 26.6 | 26.6 | 26. [symbol] | 26.6 | 26. [symbol] |
| | | Inorganic Filler 3 | 1 [symbol] .3 | 13.3 | 13.3 | 13.3 | 13.3 | 13. [symbol] | 13.3 |
| | Mold | Mold Release Agent 1 | 0.08 | 0.08 | 0.08 | 0.08 | 0.15 | 0.08 | 0.08 |
| | Release | Mold Release Agent 2 | 0.08 | 0.08 | 0.08 | 0.08 | 0.15 | 0.08 | 0.08 |
| | Agent | Mold Release Agent 3 | — | — | — | 0.15 | — | 0.14 | — |
| | | Mold Release Agent 4 | 0.23 | — | — | — | — | — | — |
| | | Mold Release Agent 5 | — | 0.23 | 0.23 | — | — | — | — |
| | | Mold Release Agent 6 | — | — | — | — | — | — | 0.23 |
| | Curing | Curing Accelerator 1 | 0.2 | 0.2 | 0.2 | 0.2 | 0.2 | 0.2 | 0.2 |
| | Accelerator | | | | | | | | |
| | Coupling | Silane Coupling Agent 1 | — | — | 0.35 | — | — | — | — |
| | Agent | Silane Coupling Agent 2 | 0.35 | 0.35 | — | 0.35 | 0.35 | 0.35 | 0.35 |
| | Pigment | Pigment 1 | 0.2 | 0.2 | 0. [symbol] | 0.2 | 0.2 | 0.2 | 0.2 |
| | Total | Parts | 100 | 100 | 100 | 100.1 | 100.1 | 100.1 | 100 |
| Evaluation | Length of | ( [symbol] 170° C.) | 215 | 210 | 223 | 200 | 205 | 205 | 180 |
| | Spiral Flow | | | | | | | | |
| | Gel Time | ( [symbol] 170° C.) | 53 | 55 | 57 | 56 | 54 | 55 | 54 |
| | Adhesion | MPa | 16.8 | 15.2 | 14.9 | 15.9 | 11.6 | 15.3 | 13.5 |
| | Strength | | | | | | | | |
| | Continuous | Evaluation | A | A | A | D | B | D | C |
| | Moldability | | | | | | | | |

[symbol]

indicates data missing or illegible when filed

The resin compositions of Examples 1 to 3 employed a mold release agent obtained by a reaction of the α-olefin-maleic anhydride copolymer with monofunctional aliphatic glycidyl ether and thus resulted in good flowability and continuous moldability as compared with the resin compositions of Comparative Examples 1 to 3.

The resin compositions of Examples 1 to 3, unlike the resin composition of Comparative Example 4, employed not a mold release agent obtained by a reaction of the α-olefin-maleic anhydride copolymer with bifunctional glycidyl ether but the mold release agent obtained by the reaction of the α-olefin-maleic anhydride copolymer with monofunctional aliphatic glycidyl ether and thus resulted in good adhesion strength and continuous moldability.

Moreover, the resin compositions of Examples 1 to 3, unlike the resin composition of Comparative Example 4, employed not the mold release agent obtained by the reaction of the α-olefin-maleic anhydride copolymer with bifunctional glycidyl ether but the mold release agent obtained by the reaction of the α-olefin-maleic anhydride copolymer with monofunctional aliphatic glycidyl ether and thus resulted in an increased length of the spiral flow and good flowability.

### REFERENCE SIGNS LIST

1 Semiconductor Device
3 Semiconductor Element
4 Encansulation Portion

1. A semiconductor encapsulating epoxy resin composition comprising:
an epoxy resin (A);
a curing agent (B);
an inorganic filler (C); and
a mold release agent (D),
the mold release agent (D) containing a reaction product (d1) of an α-olefin-maleic anhydride copolymer and monofunctional aliphatic glycidyl ether.

2. The semiconductor encapsulating epoxy resin composition of claim 1, wherein
the reaction product (d1) has a structure unit expressed by formula (C) 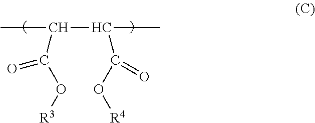
where R³ and R⁴ are each independently a hydrogen atom, a group expressed by formula (6), or a group expressed by formula (7), and at least one of R³ or R⁴ is the group expressed by formula (6) or the group expressed by formula (7) 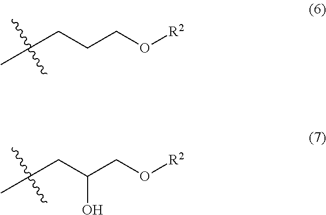
where R² in formulae (6) and (7) is an alkyl group having greater than or equal to 10 and less than or equal to 25 carbon atoms.

3. The semiconductor encapsulating epoxy resin composition of claim 1, wherein
a content of the reaction product (d1) is greater than or equal to 10% by mass relative to a content of the mold release agent (D).

4. The semiconductor encapsulating epoxy resin composition of claim 1, wherein
the epoxy resin (A) contains at least one selected from the group consisting of a biphenyl epoxy resin, a biphenyl-aralkyl epoxy resin, and a naphthol-novolac epoxy resin.

5. The semiconductor encapsulating epoxy resin composition of claim 1, wherein
a content of the inorganic filler (C) is greater than or equal to 75% by mass and less than or equal to 95% by mass relative to the semiconductor encapsulating epoxy resin composition.

6. The semiconductor encapsulating epoxy resin composition of claim 1, wherein
the monofunctional aliphatic glycidyl ether has greater than or equal to 10 and less than or equal to 25 carbon atoms.

7. A semiconductor device comprising:
a semiconductor element; and
an encapsulation portion which encapsulates the semiconductor element,
the encapsulation portion including a cured product of the semiconductor encapsulating epoxy resin composition of claim 1.
